(19) United States
(12) Patent Application Publication
(10) Pub. No.: US 2015/0118785 A1
(43) Pub. Date: Apr. 30, 2015

(54) METHOD FOR CONSISTENTLY TEXTURIZING SILICON WAFERS DURING SOLAR CELL WET CHEMICAL PROCESSING

(71) Applicant: Akrion Systems, LLC, Allentown, PA (US)

(72) Inventors: Ismail Kashkoush, Orefield, PA (US); Jennifer Rieker, Whitehall, PA (US); Gim-Syang Chen, Allentown, PA (US); Dennis Nemeth, Nazareth, PA (US)

(21) Appl. No.: 14/398,934

(22) PCT Filed: May 6, 2013
(86) PCT No.: PCT/US13/39660

§ 371 Date: Nov. 4, 2014

Related U.S. Application Data
(60) Provisional application No. 61/724,944, filed on Nov. 10, 2012.
(60) Provisional application No. 61/642,738, filed on May 4, 2012.

(51) Int. Cl. H01L 31/18; H01L 31/0236

(52) U.S. Cl. CPC H01L 31/18; H01L 31/02363
USPC 438/71

(57) ABSTRACT

A method for consistently texturizing silicon wafers dating solar cell wet chemical processing. In one aspect, the invention includes submerging a batch of silicon wafers within a process chamber having an alkaline solution mixture therein. The invention utilizes a feed and bleed technique to bleed chemicals from the process chamber and introduce fresh chemicals into the process chamber to maintain chemical concentrations within a desired range and to maintain etch by-products below a threshold. The alkaline solution etches the silicon wafers to texturize the surfaces of the silicon wafers to form a pattern of pyramids (i.e., texturization pattern) on the surface of the silicon wafers. The feed and bleed technique enables the texturization pattern on the surfaces of the processed wafers and the reflectance of the processed wafers to be consistent among different batches of silicon wafers that are submerged into the alkaline mixture in the process chamber.

### CROSS-REFERENCE TO RELATED PATENT APPLICATIONS

The present application claims the benefit of U.S. Provisional Patent Application Ser. No. 61/724,944, filed on Nov. 10, 2012 and U.S. Provisional Patent Application Ser. No. 61/642,738, filed on May 4, 2012, the entireties of which are incorporated herein by reference.

### FIELD OF THE INVENTION

The present invention relates generally to a method for controlling chemical concentration and contamination levels in an etching solution mixture during solar cell wet chemical processing to consistently texturize the surfaces of silicon wafers of different batches that are processed in the same etching solution mixture at different times.

### BACKGROUND OF THE INVENTION

A solar cell is an electrical device that converts the energy of light, such as from the sun, directly into electricity by the photovoltaic effect. The reflection of a solar cell is the amount of light energy that is reflected off of, rather than absorbed by, the solar cell. Energy that is reflected off of the solar cell cannot be used to produce electricity. Bare silicon has a high surface reflection of over 30% such that 30% of light energy is not absorbed by bare silicon. The reflection of a solar sell can be reduced by texturing the surface(s) of the silicon and by applying anti-reflective coatings to the surface(s). High-efficiency silicon solar cells need a textured front and/or rear surface to reduce reflectance and to improve light trapping. The pattern of the texture directly affects the reflectance of the solar cell.

Although the chemical reaction is well known, the anisotropic etching of silicon in alkaline solutions is a complex process. This is particularly true in the solar industry where a large mass of silicon is typically introduced into an etch bath. The etch by-products (silicates) affect the balance of the etching specie. In a typical tool that processes 200 silicon wafers per batch, approximately 2500 silicon wafers are processed per hour creating approximately 3,250 grams of by-product per hour or 71.5 kg of by-product per day. For a six-bath system, this is about 12 kg/bath, or approximately 10% weight in the solution. If adequate compensation is not made for these by-products, a significant drop in etch rate and an increase in contamination levels is typically noticed. Because of this contamination, production lines suffer from unpredictable wafer characteristics and lower cell performance.

FIG. 1 is a graph illustrating the etch rate of silicon over time (wherein time is shown in the form of a run number) according to conventional solar cell wet chemical processing techniques. The graph of FIG. 1 exemplifies the unstable etch rate that is achieved when the concentration of the etchant and the etchant by-products are not controlled. During the first run (P2) illustrated in the graph, the etch rate is approximately 0.425 μm/min/face. However, at the time of the twelfth run (A3), the etch rate has dropped to approximately 0.29 μm/min/face. It should be appreciated that although P2 is listed as the first run in FIG. 1, the run associated with P2 may be a run that occurs after the first run in a particular bath. The significant decrease in etch rate over a relatively short period of time (i.e., 12 runs) is disadvantageous in that the bath life is not maximized, which reduces the overall cost of manufacturing and cost of ownership and requires many iterations to attain the desired results. Furthermore, the decrease in etch rate may decrease consistency in the final product.

Thus, a need exists for a system and/or method that maintains a consistent etch rate at a desired level over an entire bath life and for different batches of silicon wafers that are introduced into the bath at different times. Furthermore, a need exists for a system and/or method that produces consistent texturization patterns on the silicon wafers over the entire bath life.

### SUMMARY OF THE INVENTION

The present invention is directed to a method for consistently texturizing silicon wafers during solar cell wet chemical processing. In one aspect, the invention includes submerging a batch of silicon wafers within a process chamber having an alkaline solution mixture therein. The invention utilizes a feed and bleed technique to bleed chemicals from the process chamber and introduce fresh chemicals into the process chamber to maintain chemical concentrations within a desired range and to maintain etch by-products below a threshold. The alkaline solution etches the silicon wafers to texturize the surfaces of the silicon wafers to form a pattern of pyramids on the surface of the silicon wafers. The feed and bleed technique enables the texturization pattern on the surfaces of the processed wafers and the reflectance of the processed wafers to be consistent among different batches of silicon wafers that are submerged into the alkaline mixture in the process chamber at different times.

In one aspect, the invention can be a method of texturizing surfaces of silicon wafers to form solar cells, the method comprising: providing a closed-loop circulation system comprising a process chamber and a recirculation line fluidly coupled to the process chamber, the recirculation line comprising at least one sensor; supplying an alkaline solution comprising potassium hydroxide (KOH), isopropyl alcohol (IPA) and deionized water (DIW) to the closed-loop circulation system to form a mixture having a predetermined concentration ratio and a predetermined volume, the mixture filling the process chamber and overflowing into the recirculation line; submerging a first batch of silicon wafers in the mixture within the process chamber to texturize at least one surface of the silicon wafers of the first batch to form solar cells; circulating the mixture through the closed-loop circulation system so that the mixture passes through the sensor; measuring concentration ratio of the mixture and concentration level of an etch by-product within the mixture with the sensor; comparing the measured concentration ratio to the predetermined concentration ratio to determine whether the measured concentration ratio is within a predetermined range of the predetermined concentration ratio and comparing the concentration level of the etch by-product to a predetermined threshold; upon determining that the measured concentration ratio is not within the predetermined range of the predetermined concentration ratio, feeding a volume of the KOH, the IPA and/or the DIW into the closed-loop circulation system while bleeding a substantially equal volume of the mixture from the closed-loop circulation system to return the concentration ratio of the mixture back within the predetermined range; and upon determining that the concentration level of the etch by-product is above the predetermined threshold, feeding a volume of the KOH, IPA and/or DIW into the closed-loop circulation system while bleeding a substantially equal volume of the mixture from the closed-loop circulation system to decrease the concentration level of the etch by-product in the mixture to below the predetermined threshold.

In another aspect, the invention can be a method of consistently texturizing surfaces of silicon wafers to form a solar cell that is used to create a solar panel, the method comprising: providing a closed-loop circulation system comprising a process chamber and a recirculation line fluidly coupled to the process chamber, the recirculation line comprising at least one sensor; supplying an alkaline solution comprising at least a first chemical and deionized water (DIW) to the closed-loop circulation system so as to form a mixture having a predetermined concentration ratio and a predetermined volume, the mixture filling the process chamber and overflowing into the recirculation line; submerging a first batch of silicon wafers in the mixture within the process chamber to texturize at least one surface of the silicon wafers; circulating the mixture through the closed-loop circulation system so that the mixture passes through the sensor; measuring concentration ratio of the mixture with the sensor; comparing the measured concentration ratio to the predetermined concentration ratio to determine whether the measured concentration ratio is within a predetermined range of the predetermine concentration ratio; upon determining that the measured concentration ratio is not within the predetermined range of the predetermined concentration ratio, feeding a volume of the first chemical and/or the DIW into the closed-loop circulation system while bleeding a substantially equal volume of the mixture from the closed-loop circulation system to return the concentration ratio of the mixture back within the predetermined range; and wherein the feeding and bleeding maintains a first etch rate of the silicon wafers of the first batch at a consistent rate and maintains a first reflectance of the silicon wafers of the first batch at a consistent level.

In a further aspect, the invention can be a method of consistently texturizing surfaces of silicon wafers to form a solar cell, the method comprising: providing a closed-loop circulation system comprising a process chamber and a recirculation line fluidly coupled to the process chamber, the recirculation line comprising at least one sensor; supplying an alkaline solution comprising potassium hydroxide (KOH), isopropyl alcohol (IPA) and deionized water (DIW) to the closed-loop circulation system so as to form a mixture having a predetermined concentration ratio and a predetermined volume, the mixture filling the process chamber and overflowing into the recirculation line; submerging a first batch of silicon wafers in the mixture within the process chamber to texturize at least one surface of the silicon wafers by etching the silicon wafers of the first batch at a first etch rate to form a pattern of pyramids on the surface of the silicon wafers; circulating the mixture through the closed-loop circulation system so that the mixture passes through the sensor; measuring concentration ratio of the mixture with the sensor; continuously comparing the measured concentration ratio to the predetermined concentration ratio to determine whether the measured concentration ratio is within a predetermined range of the predetermine concentration ratio; upon determining that the measured concentration ratio is not within the predetermined range of the predetermined concentration ratio, feeding a volume of the KOH, the IPA and/or the DIW into the closed-loop circulation system while bleeding a substantially equal volume of the mixture from the closed-loop circulation system to return the concentration ratio of the mixture back within the predetermined range; removing the first batch of silicon wafers from the process chamber, the silicon wafers of the first batch having a first texturization pattern; submerging a second batch of silicon wafers in the mixture within the process chamber to texturize the surfaces of the silicon wafers of the second batch by etching the silicon wafers of the second batch at a second etch rate; removing the second batch of silicon wafers from the process chamber, the silicon wafers of the second batch having a second texturization pattern; and wherein the first texturization pattern is consistent with the second texturization pattern and the first etch rate is substantially the same as the second etch rate.

### BRIEF DESCRIPTION OF THE DRAWINGS

FIG. 1 is a graph illustrating the etch rate over time according to prior art systems;

FIG. 2A illustrates the as-cut surface of a silicon wafer;

FIG. 2B illustrates the fully textured surface of the silicon wafer of FIG. 2A after processing;

FIG. 3 is a schematic illustration of an etching system according to one embodiment of the present invention;

FIG. 4 is a graph illustrating a calibration curve for KOH concentration;

FIG. 5 is a graph illustrating the amount of KOH added to the bath to maintain a constant etch rate;

FIG. 6 is a graph illustrating the concentration of the by-product in the bath;

FIG. 7 is a graph illustrating the reflectance of the wafer after processing;

FIG. 8 is a graph illustrating the consistent etch rate and reflectance utilizing the system of the present invention;

FIG. 9 is a graph illustrating experimental results of by-product (silicates) concentration when the KOH concentration is maintained constant;

FIG. 10 is a graphical representation of real-time KOH and IPA concentrations as measured by the system and as tested for accuracy by titration;

FIG. 11 is a graphical representation of real-time KOH, IPA and Si concentrations as well as an indication of when KOH and IPA are injected into the bath to maintain the concentrations at a consistent level;

FIG. 12 is a graph illustrating bath life data vs. run number; and

FIG. 13 is a graph illustrating the difference in by-product concentration without feed and bleed, with 5% volume feed and bleed from the beginning and with no feed and bleed until a predetermined by-product threshold level is reached.

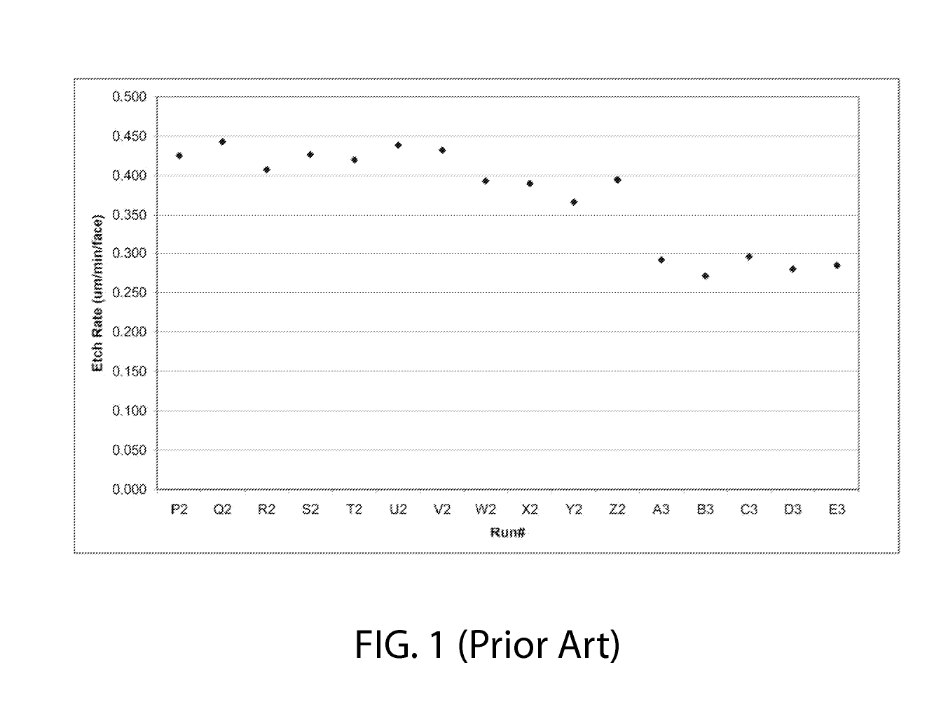

### DETAILED DESCRIPTION OF THE INVENTION

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the preferred embodiments. Accordingly, the invention expressly should not be limited to such preferred embodiments illustrating some possible non-limiting combinations of features that may exist alone or in other combinations of features; the scope of the invention being defined by the claims appended hereto.

The present invention is directed to a method for controlling chemical concentration and contamination levels (i.e., etch by-products) during solar cell wet chemical processing and thereby maintaining consistency and uniformity in the texturization of the surfaces of silicon wafers being processed into solar cells. Solar cells are created by etching a silicon wafer to form a pattern of pyramids (i.e., a texturization pattern) on the surface of the silicon wafer. This pattern of pyramids enables the light energy to bounce off the surface of the silicon wafer in such a way as to enable the silicon wafer to absorb more light. In certain embodiments, after texturization phosphorous may be diffused into a thin layer on the textured silicon wafer surface. This step gives the surface a negative potential electrical orientation. The combination of this layer and a boron doped layer below creates a positive-negative junction. Next, the silicon wafers are subjected to an anti-reflective coating to further enhance the absorption of light energy. This anti-reflective coating can be silicon nitride or any other type of material. Finally, metals are printed on opposing surfaces of the silicon wafer to enable the silicon wafer to forward collected energy to an energy storage system, such as a power grid, for later use. After the solar cells are created, a plurality of the solar cells can be connected together to form a solar panel.

The present invention is particularly directed to a method of etching of silicon wafers to create a textured surface on the silicon wafers that are used as solar cells to convert light energy into electricity by the photovoltaic effect. Utilizing the concepts discussed herein below, various batches of silicon wafers can be submerged into the same alkaline solution or other etchant solution bath at different temporal time periods (i.e., such as one right after the other) and achieve consistent texturization patterns, consistent etch rates and consistent reflectance values. In other words, using the invention discussed herein a first batch of silicon wafers can be submerged into an alkaline/etchant solution bath at time period one and a second batch of silicon wafers can be submerged into the alkaline/etchant solution bath at time period two that is after time period one and after the first batch of silicon wafers have been removed from the alkaline/etchant solution bath. Furthermore, using the invention discussed herein the silicon wafers of the first batch and the silicon wafers of the second batch will have consistent texturization patterns, consistent etch rates and consistent reflectance values. The ability to create uniform, repeatable texturization on the silicon wafers of different batches can help solar cell manufacturers reduce cost of ownership and overall cost of manufacturing by extending the usable life of the chemical bath, which in turn extends the up-time and overall utilization of the tool.

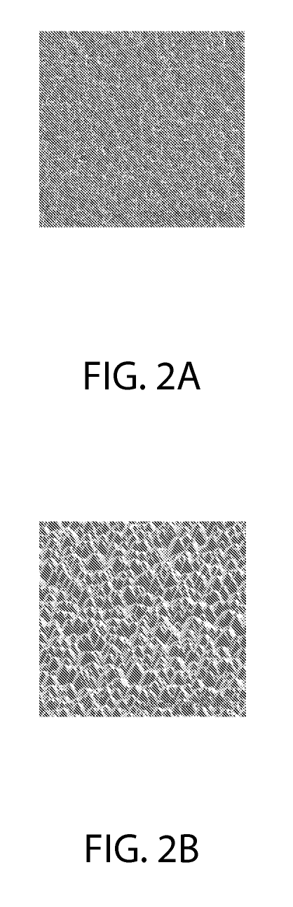

As noted above, one of the first steps in converting a bare silicon wafer into a solar cell is processing the silicon wafer in a chemical mixture in order to produce a textured surface on the silicon wafer. FIG. 2A illustrates an as-cut surface of a silicon wafer prior to processing and FIG. 2B illustrates a fully textured surface of the silicon wafer after processing. Specifically, the bare silicon wafer illustrated in FIG. 2A can be converted into the textured silicon wafer illustrated in FIG. 2B by submerging the bare silicon wafer into an etchant bath, such as an alkaline solution to thereby anisotropically etch the silicon wafer. The textured surface or surfaces of the silicon wafer form a pattern of pyramids on the surface(s) of the silicon wafer.

Chemical mixtures that are used as etchants in solar cell manufacturing to achieve the textured surface illustrated in FIG. 2B generally include KOH, KOH/IPA, HF/HNO₃, HF/HCL, alkaline NaOH, TMAH and other compounds. Furthermore, additives such as surfactants are often used to enhance etch uniformity. The invention will be described herein particularly with reference to the etchant solution being an alkaline solution comprising KOH/IPA and DIW. However, the invention is not to be so limited unless so specified in the claims and any of the chemicals noted above and other chemicals now known or later discovered for solar cell texturization can be used as would be understood by persons skilled in the art. The etchants are aqueous solutions that are mixed with an amount of water, such as deionized water. It is desirable to achieve consistency among the texturization of the fully textured surface of various wafer lots/batches, and the processing techniques described herein achieve this consistency.

It has previously been difficult to maintain consistency in the appearance of the textured surface of the silicon wafers from one lot or batch to another due to concentrations of the chemicals that form the aqueous chemical mixture changing during processing as well as the formation of an etch by-product (i.e., silicate) during processing. Specifically, in conventional techniques the etch rate of the mixture in the bath changes from batch to batch due to differences in concentration ratios from batch to batch and differences in etch by-product levels from batch to batch, which results in different texturization patterns on the surfaces of the silicon wafers of the first batch relative to the texturization patterns on the surfaces of the second (and later) batches. This is undesirable and results in the operator needing to change the bath out completely and start fresh, which increases manufacturing costs and is time consuming.

According to the inventive techniques described herein below, a reliable and accurate real-time measurement of the etching constituents can be performed in order to obtain stable and reproducible manufacturing processes that result in consistently textured silicon wafer surfaces. In addition, a mechanism can also be provided by which fresh chemicals can be added to the etching bath during the etching procedure, between wafer batches or both in order to maintain the concentration of the chemicals in the bath at a consistent level. When the chemical concentrations of the mixture within which the silicon wafers are texturized changes, the etch rate and also the resulting texturization pattern also change. Furthermore, the presence of the etch by-product above a threshold concentration level has been shown to slow down the etch rate even when the chemical concentration is correct, which also results in the texturization pattern formed on the silicon substrates changing. Simply put, the solubility of etch by-products decreases once the concentration of silicates increases. Hence, silicon mass transport from wafer surface to the etching solution is impacted. Thus, both concentration levels of the chemicals and concentration level of the etch by-products affect the etch rate, which in turn also affects the texturization of the wafer surface. The invention disclosed herein below maintains the concentration levels of the chemicals at a predetermined level and maintains the etch by-products below a threshold level.

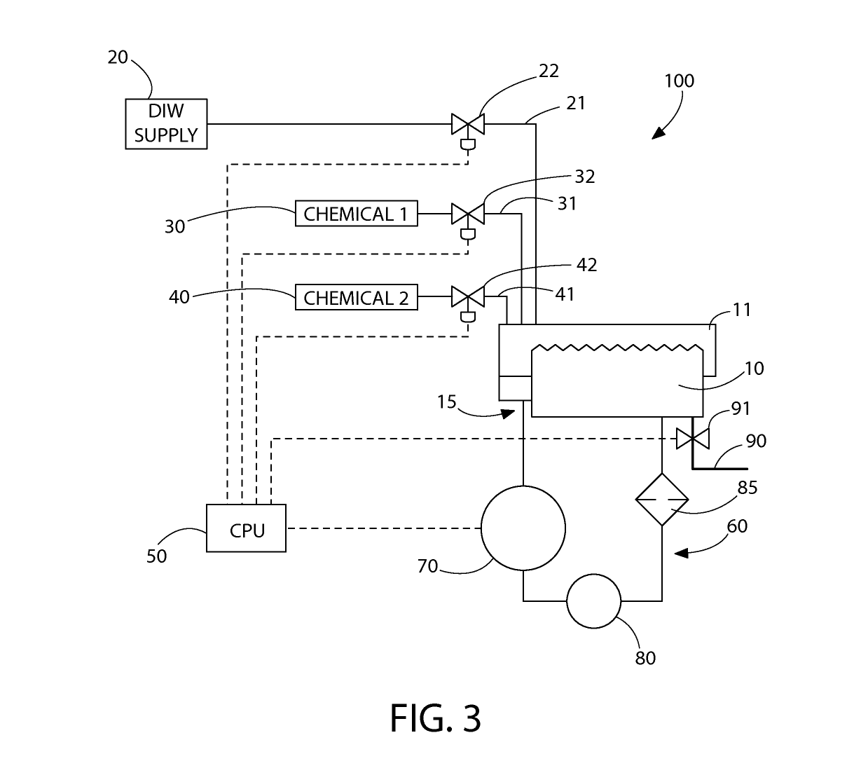

Referring to FIG. 3, a schematic illustration of a silicon wafer texturization system 100 is provided according to an embodiment of the present invention. The silicon wafer texturization system 100 comprises a closed-loop circulation system 15 comprising a process chamber 10, an overflow chamber 11 (which can be considered a part of the process chamber 10) and a recirculation line 60. The silicon wafer texturization system 100 further comprises a deionized water (DIW) supply 20, a first chemical supply 30, a second chemical supply 40 and a central processing unit (CPU) 50. Of course, the number of chemical supplies can be altered based on the number of chemicals that are needed in the etching solution mixture. Thus, in certain embodiments only one chemical supply is needed and in other embodiments more than two chemical supplies may be needed. Furthermore, the recirculation line 60 comprises at least one sensor 70, a pump 80 and a heater 85 (i.e., the sensor 70, the pump 80 and the heater 85 are operably coupled to the recirculation line 60).

In the exemplified embodiment, the DIW supply 20 is fluidly connected to a DIW dispense line 21, the first chemical supply 30 is fluidly connected to a first chemical dispense line 31, and the second chemical supply 40 is fluidly coupled to a second chemical dispense line 41. Each of the dispense lines 21, 31, 41 is positioned so as to flow the respective fluid from the respective supply into the process chamber 10 as desired and/or needed to maintain the mixture in the process chamber 10 with a desired concentration ratio and a desired etch by-product level. More specifically, the DIW dispense line 21 comprises a first valve 22, the first chemical dispense line 22 comprises a second valve 32 and the second chemical dispense line 30 comprises a third valve 42. The valves 22, 32, 42 are adjustable valves that are operably coupled to their respective dispense lines 21, 31, 41 to control the flow of the respective fluids therethrough and into the process chamber 10.

In use, the process chamber 10 is filled with the etching solution until the etching solution overflows the process chamber 10 into the overflow chamber 11. Using KOH/IPA and DIW as an example, in use the alkaline solution or etching solution comprising KOH, IPA and DIW is supplied to the closed-loop circulation system 60 to form a mixture having a predetermined concentration ratio and a predetermined volume. The mixture is made to have a specific concentration ratio by opening the valves 22, 32, 42 for a set period of time to ensure that the proper amount of each chemical (KOH, IPA and DIW) is provided in the mixture by the CPU 50 as discussed in more detail below. The mixture is made to fill the process chamber 10 and overflow into the overflow chamber 11 and into the recirculation line 60.

Upon reaching the overflow chamber 11, the etching solution will flow or be pumped via the pump 80 through the recirculation line 60. During flow through the recirculation line, the etching solution will pass through the sensor 70 so that certain measurements of characteristics of the etching solution can be taken as discussed in more detail below. Upon passing the sensor 70, the etching solution will continue to flow through the recirculation line 60 until it is fed back into the process chamber 10. This flow of the etching solution through the closed-loop circulation system 15 (i.e., through the process chamber 10 and the recirculation line 60) can be continuous in certain embodiments, or at various time periods as desired. Continuous circulation can be desired in certain embodiments so that continuous measurements of the etching solution can be taken by the sensor 70.

In certain embodiments, the sensor 70 can be any instrument capable of analyzing a mixture to determine the concentration ratio of its component parts, such as a near Infra-Red (NIR) sensor or an FT-NIR spectrometer. Furthermore, in certain embodiments the sensor 70 may include more than one sensor, or may itself be capable of measuring more than one characteristic of the etching solution. For example, in certain embodiments the sensor 70 may also include a particle counter for tracking the number or percentage of particles, such as etch by-product particles that are present in the mixture in the process chamber 10. The sensor 70 is installed in the recirculation line 60 of the process chamber 10. NIR sensors measure light absorbance and transmit it through fiber optic cables to an array of detectors. Finally, the silicon wafer texturization system 100 includes a bleed line 90 having a bleed valve 91. The bleed line 90 is fluidly coupled to a bleed port of the process chamber 10 so that liquids can be drained from the volume of the process chamber 10 during wafer processing. The bleed valve 91 is adjustable so that the flow rate of fluids through the bleed line 90, and thus out of the closed-loop circulation system 15, can be controlled.

Each of the first, second and third valves 22, 32, 42 and the sensor(s) 70 are operably coupled to the CPU 50 for communication therebetween. Furthermore, the bleed valve 91 is also operably coupled to the CPU 50. These operable connections can be facilitated via the appropriate electric, fiber-optic, cable or other suitable connections, which are illustrated in dashed lines in FIG. 3. The central processing unit 50 is a suitable microprocessor based programmable logic controller, personal computer or the like for process control and preferably includes various input/output ports used to provide connections to the various components of the etching system 100 that need to be controlled and/or communicated with.

The central processing unit 50 also preferably comprises sufficient memory to store process recipes, parameters, and other data, such as a predetermined (i.e., target) concentration ratio, a predetermined etch by-product particle count, a predetermined range, flow rates, processing times, processing conditions, and the like. The central processing unit 50 can communicate with any and all of the various components of the etching system 100 to which it is operably connected in order to automatically adjust process conditions, such as activating flow through any one of the feed lines 21, 31, 41 either alone or in combination, activating flow through the bleed line 90, pump activation, heat application, and filtering. While not illustrated, the central processing unit 50 can also be operably coupled to the heater 85 and the pump 80 if desired.

The CPU 50 is also programmed with the proper algorithms to receive data signals from the sensor 70, analyze the incoming data signals, compare the values represented by the incoming data signals to stored values and ranges, and automatically make the appropriate adjustments to the etchant being used to process the wafers by feeding fresh etchant components into the circulation via lines 21, 31, 41 and/or bleeding contaminated/old etchant via the bleed line 90 to achieve a predetermined characteristic within the etchant mixture. For example, the CPU 50 can store a predetermined value and a predetermined acceptable operating range for concentration ratio and/or etchant by-product. More specifically, the CPU 50 can be set to store a desired concentration ratio of the KOH, the IPA and the DIW in the etching solution that flows through the closed-loop recirculation system 15. In such embodiments, the sensor 70 will continually transmit the actual measured concentration ratios of the KOH, the IPA and the DIW in the etching solution. The CPU 50 will compare the actual concentration ratios of the KOH, the IPA and the DIW with the desired concentration ratios of the KOH, the IPA and the DIW and if they are different, the CPU 50 will open and close the valves 22, 32, 42, 91 as needed to feed new chemical into the process chamber 10 while bleeding some of the etching solution mixture from the process chamber 10 to change the concentrations of the various chemicals and again achieve the desired concentration ratio.

In certain embodiments, the chemical concentration set points of the various chemicals and the DIW are preset by a user. Specifically, in one embodiment the chemicals used for the etchant are DIW, KOH and IPA. The user will define a concentration set point for each of the DIW, KOH and IPA and store those concentration set points in the memory of the CPU 50. In one embodiment, the concentration level of the KOH is below 10% by weight, more specifically between 2% and 10% by weight, and still more specifically between 2% and 6% by weight. Furthermore, in one embodiment the concentration level of the IPA is below 10% by weight, more specifically between 2% and 10% by weight, and still more specifically between 2% and 6% by weight. Of course, the concentrations of the KOH and IPA are not to be limited in all embodiments unless specifically recited in the claims.

The CPU 50, through its proper programming and algorithms, will maintain each chemical within its band and tolerance of concentration and temperature based on the set points provided by the user. The bands and tolerances are also defined by the user, and may be plus/minus 2% variations from the concentration provided. Thus, if the set point concentration for the KOH and the IPA is 5% by weight, the band and tolerance may enable variations in those concentrations down to 3% by weight and up to 7% by weight before initiating the feed and bleed techniques described herein. The CPU 50 will cause the system 100 to inject chemicals and water and to bleed the bath from the process tank 10 in durations and intervals defined by the user to maintain the set point or on an as-needed basis to correct the concentrations of the various chemicals.

During wafer processing in the process chamber 10, loss of chemicals occurs, which can alter the desired concentration percentages of the various chemicals. For example, in a bath of KOH, IPA and DIW, if the KOH is lost at a higher percentage than the loss of the IPA and the DIW, then the concentration of the chemicals in the bath will be determined by the CPU 50 to be incorrect. Specifically, utilizing data transmitted from the sensor(s) 70, such as the NIR sensor, the CPU 50 will compare the concentrations of the chemicals to a desired concentration that is stored in the memory. Upon making a determination that the concentration is not within the band and tolerance of the desired concentration, the CPU 50 will open any one of the valves 22, 32, 42 to enable the DIW, the first chemical (i.e., KOH) and/or the second chemical (i.e., IPA) to flow into the process chamber 10 in order to obtain/maintain the desired concentration.

In certain embodiments, the sensor 70 monitors the concentration levels of the various chemicals in the bath in the process chamber 10 continuously, such as many times per second so as to be essentially continuous. In other embodiments, the sensor 70 monitors the concentration levels of the various chemicals in the bath in the process chamber periodically according to a predetermined pattern or schedule.

Upon receipt of data from the sensor 70, the CPU 50 analyzes the data signals and compares the measured values to predetermined/desired values that are stored in its memory. More specifically, the measured concentration ratio is compared to a stored predetermined/desired concentration ratio to determine whether the measured concentration ratio is within a predetermined/acceptable range (i.e., plus/minus 2%) of the predetermined concentration ratio.

In certain embodiments, when the CPU 50 determines that the chemical concentration is not within the desired band and tolerances as defined by the user, the CPU 50 will cause the bleed valve 91 to open to bleed an amount of the bath from the process chamber 10. The CPU 50 will, either simultaneously, or after bleeding from the bath, open any of the valves 22, 32, 42 as needed to refill the process chamber 10 with the chemicals in the desired concentration. Thus, the system 100 may use a feed and bleed technique to achieve the desired concentrations, or the system 100 may simply inject chemicals and water at a desired time interval to compensate for the loss of chemicals or change in chemical concentrations without utilizing the bleed technique.

Similarly, the CPU 50 monitors the content of etch by-products, such as silicate, to ensure that they remain below a desired threshold. The desired threshold can be a value that is stored in the memory device of the CPU 50 so that the CPU 50 can determine when the threshold has been reached and can cause the system to operate in order to maintain the by-product concentration below the threshold. Specifically, when the content of silicate or other by-products increases above a desired threshold, it has been determined that the etch rate is significantly slowed down. In certain embodiments, the threshold of etch by-products that the system is designed to maintain is 100 ppm. However, this threshold is dependent on the desired end results for etch rates and pyramid dimensions after texturization and can be above 100 ppm in other embodiments.

In order to maintain a constant etch rate, it is desirable to maintain the silicate or other by-product content below the threshold as discussed above. Upon the sensor 70 transmitting data to the CPU 50 that indicates that the silicate or other etch by-product content is at or above the desired threshold, the CPU 50 will open the bleed valve 91 to bleed a portion of the bath from the process tank 10. In certain embodiments, the amount of liquid that is bled from the bath via the bleed line 90 is between 0-10% by volume, more preferably between 3-8% by volume, and more preferably approximately 5% by volume. Of course, the invention is not to be limited by the particular volume of the bath that is bled during this process in all embodiments. At the same time or subsequent to the bleed step, the CPU 50 will open the valves 22, 32, 42 as desired to add the same volume of the mixed chemicals that was previously drained. Bleeding the bath from the bleed line 90 and feeding additional chemicals into the process chamber 10 results in decreasing the silicate by-product concentration in the bath because the liquid with the by-product contained/dissolved therein is removed from the process chamber 10 and additional chemicals are added to the process chamber without the by-product. Moreover, in certain embodiments the system 100 will replenish the bath within the process chamber 10 with the known chemical mix if the liquid level drops for any reason.

As noted above, the system disclosed herein is able to maintain a consistent etch rate on the silicon wafers that are processed within the process chamber 10 over the entire bath life even for multiple batches, is able to maintain a consistent reflectance on the silicon wafers that are processed in the process chamber 10 over the entire bath life even for multiple batches and is able to maintain a consistent texturization pattern on the surfaces of the silicon wafers that are processed within the process chamber 10 over the entire bath life even for multiple batches. In certain embodiments, it is desirable to maintain the etch rate at below 1 μm/min, more specifically between about 0.2 μm/min and about 0.8 μm/min and still more specifically between about 0.3 μm/min and about 0.5 μm/min. Furthermore, in certain embodiments it is desirable that the silicon wafers that are processed in the process chamber 10 have a reflectance that is below 10.0% at 950 nm wavelength, and more specifically a reflectance that is between about 8.0% and about 10.0% at 950 nm wavelength.

Operation of the silicon wafer texturization system 100 of the present invention will now be discussed wherein KOH, IPA and DIW are used as the etching/alkaline solution. A batch of silicon wafers in need of texturization in order to form solar cells from the silicon wafers is provided. The silicon wafers in the batch are silicon wafers for solar cell manufacturing and are generally crystalline silicon such as monocrystalline silicon or polycrystalline silicon. Of course, other types of silicon wafers that are used for solar cell manufacture can be used in the inventive system. All valves 22, 32, 42, 91 are in the closed position initially at the beginning of the process.

First, the adjustable valves 22, 32, 42 are switched to an open position (in response to signals sent from the CPU 50 or manually by a user) so that DIW, KOH and IPA are dispensed via lines 21, 31, 41 into the process chamber 10. As the DIW, KOH and IPA are supplied to the process chamber 10, the DIW, KOH and IPA combine to form a mixture. The adjustable valves 22, 32, 42 control the flow rates of the DIW, KOH and IPA through the dispense lines 21, 31, 41 so that the mixture is created with a predetermined/desired concentration ratio of DIW, KOH and IPA. In one embodiment, the mixture has between 2% by weight and 10% by weight KOH, or more specifically between 2% by weight and 6% by weight KOH, between 2% by weight and 10% by weight IPA, or more specifically between 2% by weight and 6% by weight IPA, and the remainder DIW. However, any other concentrations and weight percentages of the various chemicals can be used. The DIW, KOH and IPA continue to be supplied via the lines 21, 31, 41 until the mixture overflows the process chamber 10 into the overflow chamber 11 and into the recirculation line 60. Once a predetermined volume of the mixture is supplied to and formed in the closed-loop circulation system 15, the valves 22, 32, 42 are closed, thereby discontinuing the supply of the DIW, KOH and IPA. The valves 22, 32, 42 can either be closed in response to signals transmitted from the CPU 50 or manually by a user.

At this point, the pump 80 is activated, causing a cyclical flow of the mixture from the process chamber 10 (via the overflow chamber 11), through the recirculation line 60 and back into the process chamber 10. As the mixture passes through the recirculation line 60, it passes through the heater 85 in embodiments that include a heater 85 and can also pass through a filter if desired. The mixture also passes by the sensor 70. As discussed above, the sensor 70 continuously measures the concentration ratio of the mixture and/or the various concentrations of each of the chemicals in the mixture and/or the etch by-product levels as the mixture passes through the recirculation line 60. The continuous measurements of concentration levels and etch by-product levels can be performed many times per second so as to be essentially continuous or periodically according to a predetermined pattern. The concentration sensor 70 creates data signals indicative of the measured concentration ratio of the mixture and the measured etch by-product levels of the mixture and transmits these signals to the CPU 50 for processing via its electrical connection.

Upon receipt of the data signals from the sensor 70, the CPU 50 analyzes the data signals and compares the measured values to predetermined/desired values stored in its memory. More specifically, the measured concentration ratio is compared to a stored predetermined/desired concentration ratio to determine whether the measured concentration ratio is within a predetermined/acceptable range of the predetermined concentration ratio. The measured etch by-product level is compared to a stored predetermined/desired etch by-product level to determine whether the measured etch by-product level is greater than the predetermined etch by-product level.

Upon comparing the measured concentration ratio and etch by-product level of the mixture flowing through the recirculation line 60 to the predetermined/desired concentration ratio and etch by-product level, the CPU 50 determines whether the measured concentration ratio is within the predetermined range of the predetermined concentration ratio and whether the etch by-product levels are below the threshold. If the CPU 50 determines that the measured concentration ratio and the measured etch by-product level are within the predetermined ranges and levels, no action is taken and the process chamber 10 is ready for processing of the first batch of silicon wafers. Specifically, at this time the initial step of ensuring that the mixture has proper concentration levels has been completed and the first batch of silicon wafers can be submerged in the process tank 10.

While the first batch of silicon wafers are submerged in the process tank 10, the mixture continues to flow through the recirculation line 60 (due to operation of the pump 80) and the mixture therefore continues to be analyzed for concentration ratios and etch by-product levels. As processing takes place, the etch by-products start to form in the mixture and the concentration ratios and levels of the various chemicals start to change. Upon the sensor 70 transmitting values to the CPU that are outside of the ranges and levels, the CPU 50 will open the valves 22, 32, 42 as needed to add KOH, IPA and DIW into the process chamber 10 and the CPU 50 will open the valve 91 as needed to bleed the mixture from the process chamber 10 until the sensor 70 transmits signals to the CPU 50 indicating that the concentration ratios and the etch by-product values are within the predetermined ranges and values as stored in the CPU 50 memory.

As an example, if the sensor 70 transmits a signal to the CPU 50 that indicates that the concentration level of the KOH has dropped to below the predetermined/desired level, the CPU 50 will open the necessary valve to inject additional KOH into the process chamber 10 and into the mixture. Furthermore, the CPU 50 may also open the valve 91 to bleed or drain some of the mixture from the process chamber 10 if needed. Furthermore, if the sensor 70 transmits a signal to the CPU 50 that indicates that the etch by-product level has increased beyond the threshold level, the CPU 50 will open the valve 91 to bleed the mixture from the process chamber 10 and will also open the valves 22, 32, 42 as needed to maintain the closed-loop system 15 filled with the mixture and to ensure that the concentration levels of the various chemicals is proper. In certain embodiments, the volume of the mixture that is bled from the process chamber 10 is substantially the same as the total volume of chemicals that is added into the process chamber 10.

The measuring of the concentration ratios and the etch by-product levels of the mixture occurs while the first batch of silicon wafers are being processed in the process chamber 10. Specifically, the pump 80 forces flow of the mixture through the closed-loop circulation system 15 during the entire loading and processing times of the batches of silicon wafers and the sensors 70 continue to perform their measuring functions during silicon wafer processing and loading. The feeding and bleeding continues while the wafers continue to be processed until a desired volume of the mixture has been bled and replaced such that the etch by-product level and the concentration ratios/levels of the chemicals of the mixture within the closed-loop circulation system 15 returns to the predetermined/desired levels. The user can program the appropriate volume to be bled and fed for various conditions based on measured etch by-product level and the overall predetermined volume of the mixture initially supplied to the process chamber 10. In this way, the etch by-product levels and the concentration ratios of the chemicals can be dynamically controlled during wafer processing.

When the first batch of silicon wafers are done being processed, the first batch of silicon wafers are removed from the process chamber 10. During this entire time, the pump 80 continues to operate and the mixture continues to flow through the recirculation line 60 so that the sensor 70 continues to measure the characteristics of the mixture discussed above and transmit signals to the CPU 50. Thus, even during removal of a batch of wafers from the process chamber 10, the feed and bleed techniques discussed above can occur to maintain the concentration levels/ratios and etch by-product level of the mixture at the desired levels. Upon removal of the first batch of silicon wafers from the process chamber 10, at least one surface of the silicon wafers of the first batch have a first texturizing pattern thereon. It should be noted that if it is desired to texturize both surfaces of the silicon wafers, then the silicon wafers are submerged in the process chamber 10 without any coating. However, if it is only desired to texturize one of the surfaces of the silicon wafers, then the other surface of the silicon wafers can be masked with a layer, such as Si₃N₄, SiO₂, or photoresist.

Next, while the pump 80 continues to operate and the mixture continues to flow through the recirculation line 60, a second batch of silicon wafers is submerged into the mixture within the process chamber 10 for processing. The feed and bleed techniques discussed above continue to take place during submersion and processing of the second batch of silicon wafers. Due to the feed and bleed techniques, the etch rate is consistent while the first batch of silicon waters are being processed and the second batch of silicon wafers are being processed. The etch rate being consistent means that the etch rate is substantially the same or remains within substantially the same range (such as between 0.2 μm/min and 0.7 μm/min or between 0.3μ/min and 0.5 umin) during processing of the first batch of silicon wafers and during processing of the second batch of silicon wafers. After the processing time is complete, the second batch of silicon wafers are removed from the process chamber 10. The silicon wafers of the second batch have a second texturization pattern on at least one surface thereof.

Due to the feed and bleed technique discussed above, the concentration ratios of the chemicals is maintained consistent and the etch by-product level is maintained consistent and below a threshold during processing of both the first batch and the second a batch of silicon wafers. As a result, the second texturization pattern is consistent or uniform with the first texturization pattern. Furthermore, due to the feed and bleed technique discussed above, the reflectance of the silicon wafers of the first batch is consistent or substantially the same or within substantially the same range as the reflectance of the silicon wafers of the second batch. In certain embodiments, the reflectance of the silicon wafers of the first and second batches is between approximately 8% and 10% at 950 nm wavelength.

Furthermore, a third, fourth, fifth and so on batch of silicon wafers can be submerged in the mixture within the process chamber 10 and still achieve the same results as the first batch of silicon wafers due to the feed and bleed techniques discussed herein. Specifically, because the etch rate, the chemical concentrations and the etch by-product levels are maintained substantially the same throughout the bath life of the mixture, every batch of silicon wafers processed in the mixture in the process chamber 10 will have similar, consistent and uniform characteristics in terms of reflectance and texturization pattern. Reflectance is the result of completeness of the texturization process, pyramid size and distribution. By keeping the texturization pattern uniform from batch to batch, the reflectance and quality of the solar cells can also be maintained uniform and consistent.

### Example

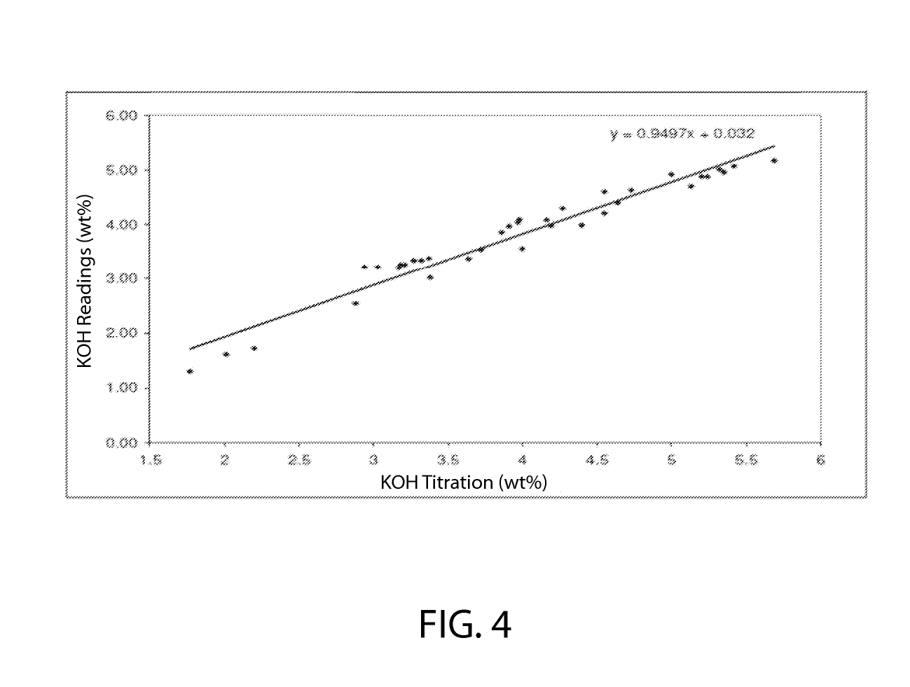

Referring to FIGS. 4-9, an experiment that was conducted to test the effectiveness of the system 100 will be described. Wet chemical processes were conducted on a fully-automated GAMASolar™ wafer etching and cleaning station. The batch size was 200 wafers per run. All tests were performed with the same wafer supplier, including wafers from about 100 different ingots. Silicon etching processes were conducted with the aid of an in-situ chemical concentration control system. Measurements of concentrations were taken using inline NIR (near Infra-Red) sensors installed in the recirculation loop of the process tanks. These sensors measure light absorbance and transmit it through fiber optics cables to an array of detectors (spectrophotometer).

The light absorbance of given specie in the solution, as measured by the sensor 70 (i.e., NIR sensor) is correlated to its concentration over a wide range of wavelengths. Specifically, prior to using the sensor 70 in testing situations, the sensor 70 is calibrated to teach the sensor 70 to correlate various light absorbances with a particular concentration. FIG. 4 illustrates a graphical representation of the calibration procedure for KOH. The sensor 70 is placed in a bath having a certain known percentage of KOH (i.e., 1%, 2%, 3%, etc.). The sensor 70 measures the light absorbance of the bath, and can correlate the particular light absorbance with a particular concentration of KOH. The sensor 70 can then be used to monitor the concentration of the KOH during use of the system, and the CPU 50 can add KOH into the bath as needed based on the data transmitted from the sensor 70 to the CPU 50. The same procedure takes place for training the sensor 70 regarding the IPA or any other chemical concentrations.

A signal is obtained by the sensor and is then reported to an amplifier that scales the response to a 4-20 mA output. This signal is subsequently fed into an analog module that scales the signal and reports directly to the system computer (i.e., CPU 50) which controls the spiking (volumes and frequency) of chemicals to maintain concentration as discussed in detail above. In other words, the CPU 50 causes additional amounts of the chemicals (KOH, IPA, etc.) into the bath based on the signals received from the sensors 70 regarding the concentrations of the chemicals. A variety of chemicals e.g. HF, HNO₃, HAc and applications were also studied but only the results of KOH/IPA control are presented here. The goal was to produce consistent etch rates and texturization patterns similar to those shown in FIG. 2B over the entire bath life and different silicon loading levels.

This technology provides technical advantages by accurately measuring the concentration of chemicals to produce the desired process results, in this case a consistent texturization pattern. Controlling concentration for uniform, repeatable texturization will help solar cell manufacturers reduce cost of ownership (COO) and overall cost of manufacturing by extending the usable life of the chemical bath, which in turn extends the up-time and overall utilization of the tool.

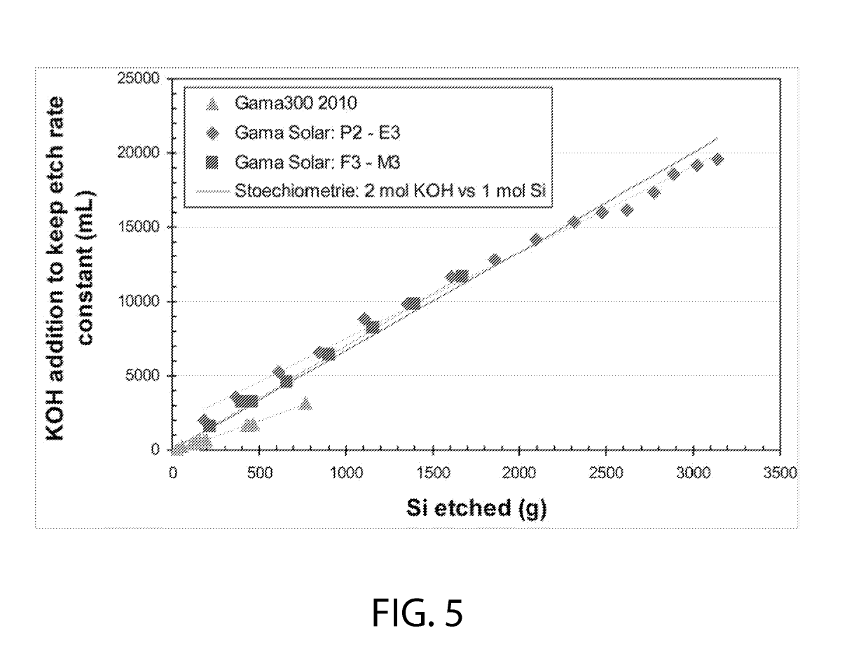

Referring to FIG. 5, a graphical representation is provided that shows the amount of KOH that is required to maintain a stable etch rate over time. As more silicon is etched over time, more KOH is added in order to maintain the etch rate at a constant level. Specifically, the KOH is used to etch the silicon wafers and therefore the levels of KOH in the mixture decrease over time. More KOH is needed to be added in order to maintain the etch rate at a consistent and substantially constant level. As can be seen from FIG. 5, the volume of KOH required for maintaining a constant etch rate (ER) is linearly related to the mass of silicon being etched. The data is in excellent agreement with stoichiometry and stands good grounds for production applications.

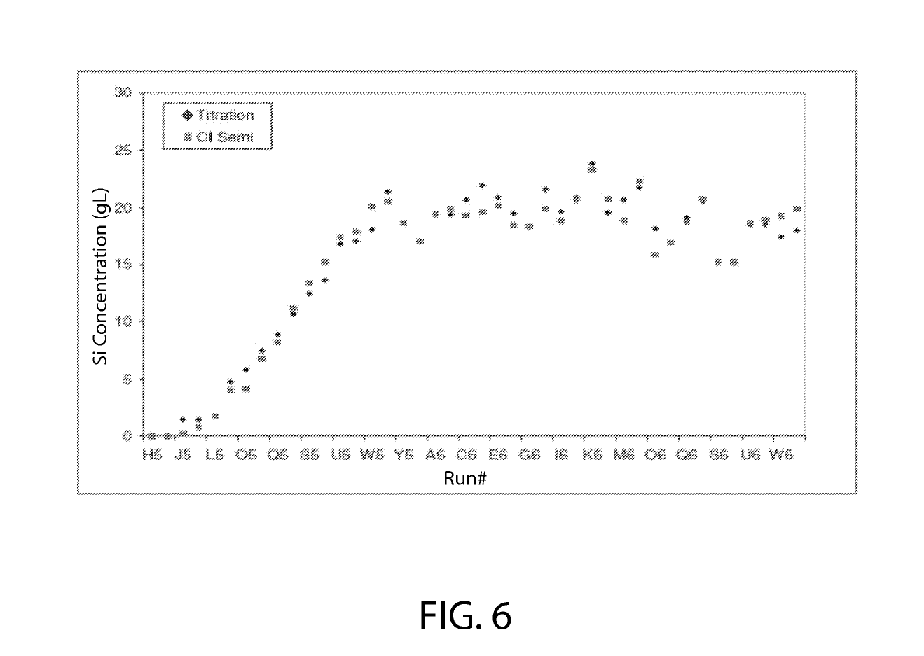

Referring to FIG. 6, a graphical representation is provided showing the concentration of etch by-products in the bath/mixture over time. As discussed above, the system is calibrated to track the etch by-products (measured as Si in the graph of FIG. 6). Thus, in addition to tracking the concentration of the various chemicals, the system tracks and monitors the concentration of the etch by-products. Over time (as seen from lot H5 to lot Y5 in FIG. 6), the concentration of the etch by-products continues to rise from 0 g/L to approximately 20 g/L. However, once the by-product concentration reaches its threshold value, which in the exemplified embodiment is approximately 20 g/L, the system maintains the etch by-product concentration at that level. Specifically, the system does not cause the by-product concentration level to significantly increase or decrease, but rather maintains it just below the desired threshold value utilizing the feed and bleed processing techniques described herein above.

Results have shown that the dissolved etch by-products in the bath/mixture must be maintained below a threshold limit in order to maintain the etch rate consistent/constant and to therefore create solar cells having consistent texturization patterns and consistent reflectance values. In accordance with the present invention, the CPU 50 is programmed with an algorithm to control the etch by-product concentration in the bath, so the etch rate is maintained. This algorithm utilizes a feed and bleed technique that causes the system to bleed a certain volume of the bath from the process tank 10 while also injecting known volumes of fresh chemicals into the process tank 10. The system is therefore able to maintain the concentrations of chemicals as well as the etch by-products at a predetermined level within a tolerance.

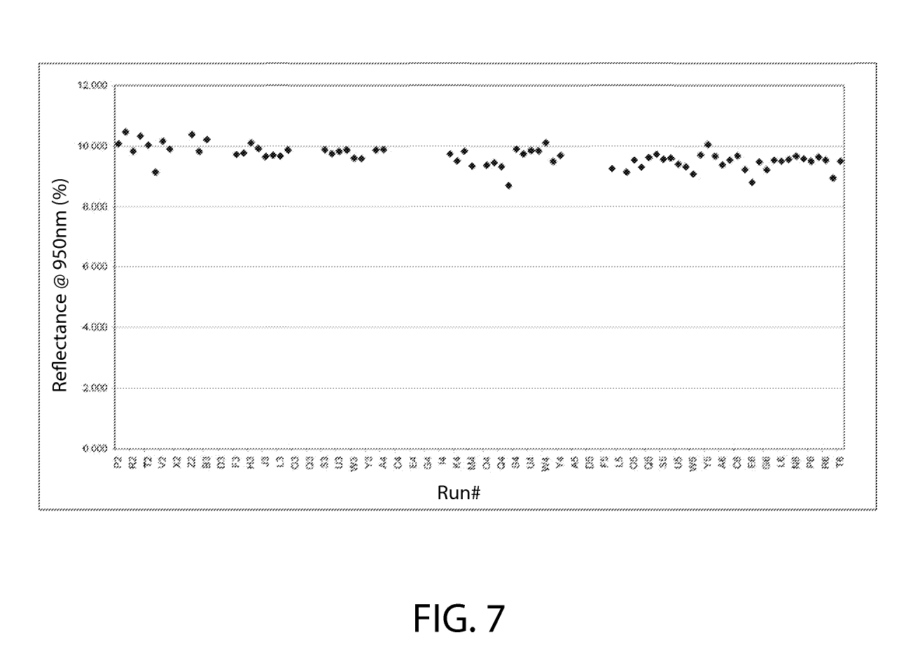

As a result of maintaining the concentrations of the chemicals at a desired level within a tolerance and maintaining the etch by-products below a predetermined threshold, consistent wafer texturization and reflectance can be achieved. FIG. 7 is a graphical representation of the reflectance of the texturized wafers after processing using the system described herein. As can be seen, there is substantial consistency between the various lots or batches of wafers in terms of their reflectance (approximately 10% at 950 nm wavelength). Specifically, the first batch of silicon wafers submerged in the bath is batch or run number P2. In batch number P2, the reflectance of the silicon wafers is approximately 10.1%. In the following batches (i.e., batches 2-10 indicated as run number R2 through H3), the reflectance varies between about 9.00% and about 10.4%. In fact, in the fifty batches that were run (indicated as run number P2 through run number T6), the reflectance only varies from a low point of about 8.9% to a high point of about 10.4%, and most of the silicon wafers have a reflectance value of between about 9.6% and 10.2% after texturization using the processing techniques and the feed and bleed techniques discussed herein above. Thus, maintaining the chemical concentrations consistently within a tolerance and maintaining the etch by-product concentration consistently below a threshold produces solar cells having consistent reflectance values despite the solar cells or silicon wafers being processed completely separately in separate batches at different times, but within the same mixture and within the same process tank.

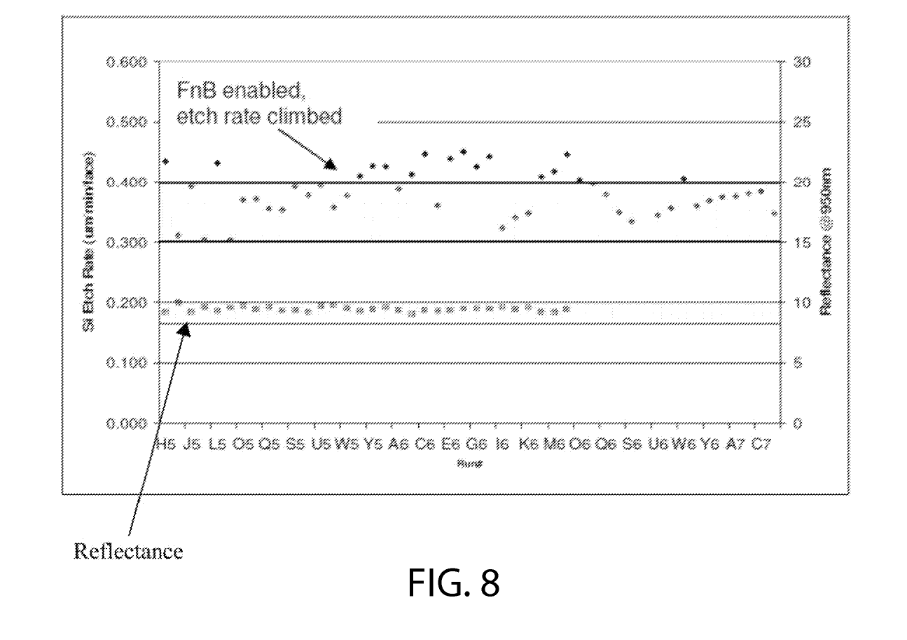

Referring to FIG. 8, a graphical representation of the etch rate and the reflectance of the texturized wafers after processing using the system described herein is provided. In the exemplified embodiment, when the feed and bleed techniques of the present invention are utilized, the etch rate is maintained consistently within a band between 0.3-0.45 um/min/face. Furthermore, the processed wafers have a reflectance value that is consistently approximately 10% (or more specifically between about 8.5% and 10.0%) at 950 nm as discussed above. Thus, the process techniques of the present invention achieves processing with a relatively consistent etch rate, which produces wafers having a consistent reflectance even among different and separate batches or runs.

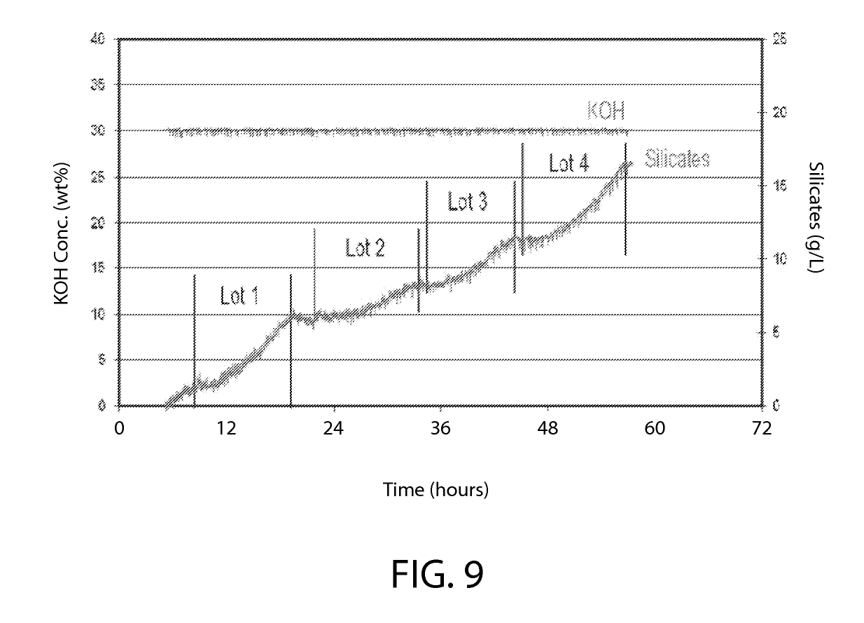

Referring to FIG. 9, a real-time graphical representation of the etch by-product (silicate) and the KOH is illustrated. The graph of FIG. 9 illustrates that the system maintains the KOH concentration at a constant level (i.e., 30 wt %) from hour zero of processing to hour 60 of processing. The KOH concentration is maintained at the constant level utilizing the chemical injection techniques described herein above. During this time period, the concentration of the silicates continues to increase because it has not yet reached the threshold value. Upon the silicate concentration reaching the threshold value, the system will operate the feed and bleed techniques disclosed herein in order to maintain the silicate concentration levels just below the threshold.

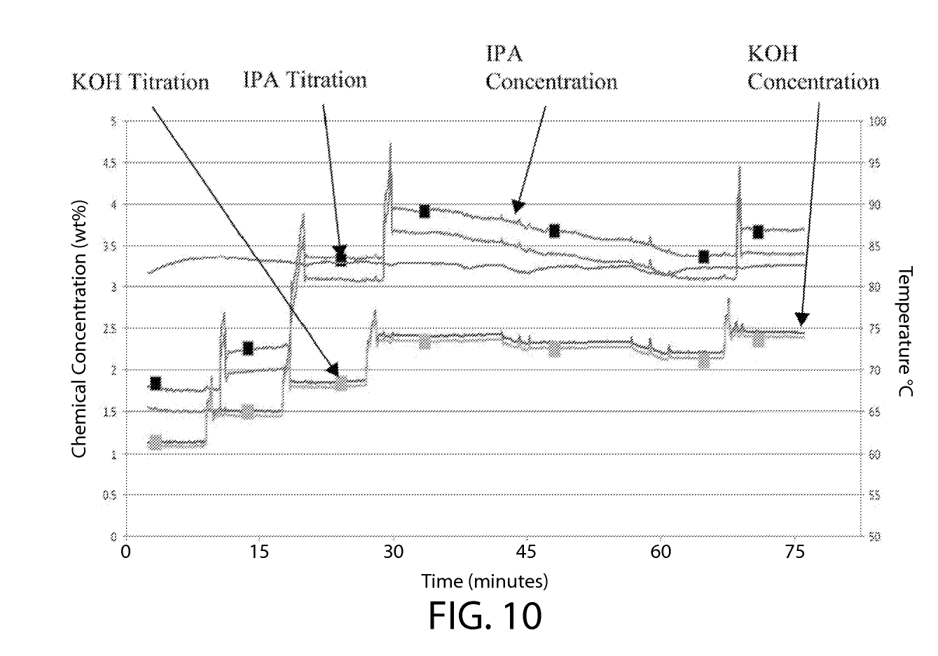

Referring to FIG. 10, a graphical representation of the calibration technique is provided.

FIG. 10 exemplifies the concentrations of KOH and IPA using the sensor. FIG. 10 also illustrates that the concentrations of KOH and IPA are tested using titration to ensure and maintain the accuracy of the sensor. In this embodiment, the feed and bleed technique was used to maintain the KOH concentration between about 2-2.5% by weight and to maintain the IPA concentration between about 3-4% by weight. The exact concentration of the KOH and the IPA can vary depending on the resulting desired characteristics of the texturized silicon wafer.

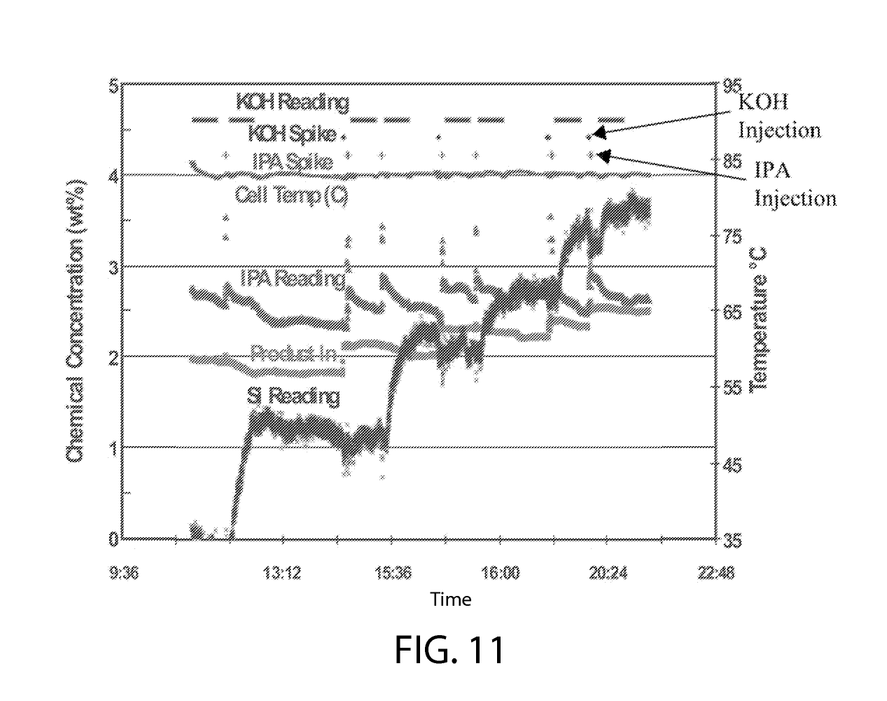

FIG. 11 is a graphical representation of the concentrations of silicon by-products, IPA, KOH and temperature. FIG. 11 also illustrates the timing intervals at which KOH and IPA are injected into the bath/mixture in order to maintain the KOH and IPA concentration levels within the tolerance band. Thus, utilizing the processing techniques described herein, the KOH and IPA concentration readings are maintained relatively consistent. Furthermore, the silicon by-product concentration reading continues to increase. However, upon the silicon by-product concentration level reaching the threshold, the system will begin the feed and bleed techniques to maintain the silicon by-product concentration level below the threshold.

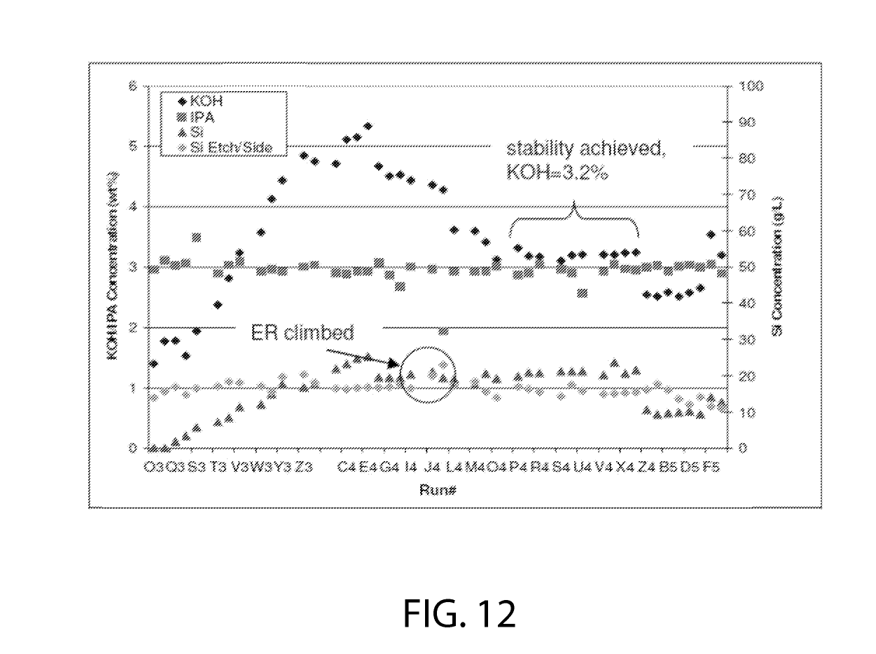

In FIG. 12 another graph of an experiment illustrating the KOH and IPA concentrations and the etch by-product values over various batches or run numbers in the mixture is provided. As can be seen, the etch by-product level is maintained at a fairly constant concentration of about 20 g/L over all of the runs/batches. Furthermore, the IPA is also fairly constant at about 3.0% by weight over all of the runs/batches. The KOH increases in concentration over the first ten or eleven runs and then decreases until it reaches stability at about 3.2% by weight.

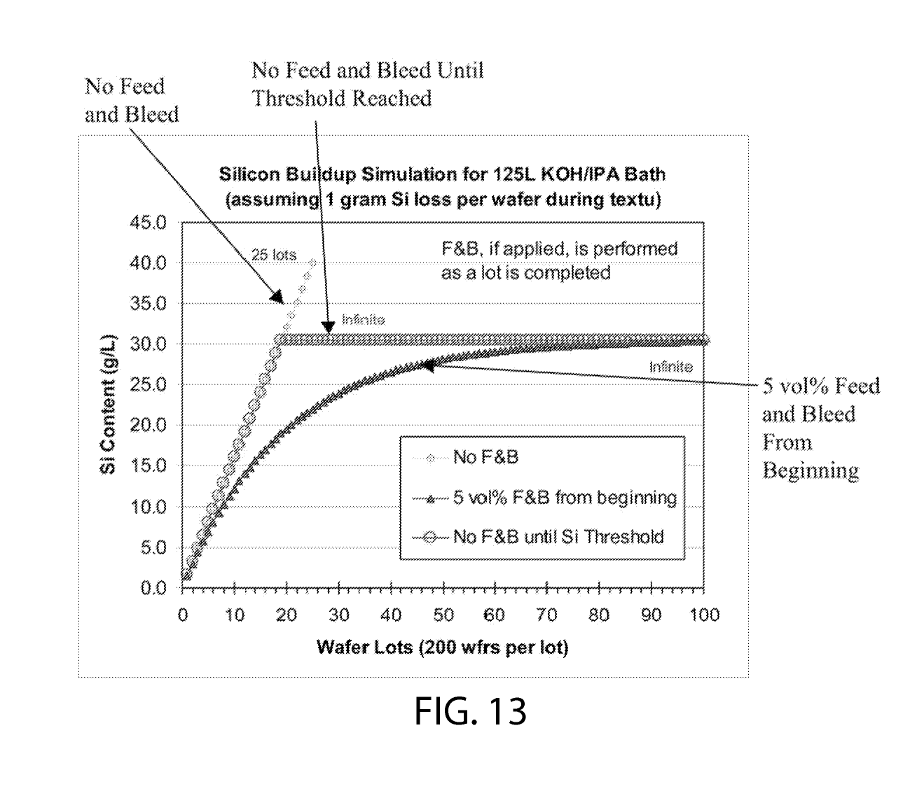

Finally, referring to FIG. 13 a graphical representation of the silicon by-product concentration is illustrated utilizing different techniques. As noted, the graph illustrates the silicon concentration when the inventive feed and bleed techniques are not used, when the inventive feed and bleed techniques are only used when the silicon concentration reaches the threshold, and when the inventive feed and bleed technique is used from the beginning of the processing with a 5% volume feed and bleed. It can be seen that when no feed and bleed is used, the silicon concentration steadily rises in a linear fashion and is at approximately 40.0 g/L after approximately 26 wafer lots are processed in the bath.

When feed and bleed is not used until the silicon by-product concentration reaches the threshold (which is 30.0 g/L in the exemplified embodiment), the silicon by-product concentration level rises steadily until reaching that threshold, at which time the silicon by-product concentration level is maintained at the threshold. Although the invention is described herein with the threshold being 30.0 g/L, the threshold can be any concentration value as determined by the user. The threshold value is stored in the memory of the CPU 50 so that the CPU can ensure that the silicon by-product is maintained at the desired level.

Finally, when the feed and bleed is used to feed and bleed 5% by volume of the bath after each lot is completed, the silicon by-product concentration level rises slower than in the previous embodiments until it flattens out at the threshold value. Thus, using feed and bleed from the beginning or only after the threshold is reached achieves the same silicon by-product concentration levels (i.e., 30 g/L) after approximately 80 wafer lots are processed in the bath.

In certain embodiments of the invention, the mass of silicon removed from the wafers (i.e., the silicon concentration) will be calculated based on an assumed etch rate. The inventive system will compare the estimated/assumed silicon concentration with the actual silicon concentration and will transmit an alarm to the user if there is a significant difference in values so that the user can determine whether to proceed with processing or to terminate processing.

Furthermore, if the etch by-products affects the signal accuracy, the system will allow the user to input an offset so the reading of the actual concentration of the etch by-product is accurate. In other words, the same bath can be used in the process chamber for days, weeks or months utilizing the inventive system to inject chemicals and feed/bleed the bath to maintain a consistent etch rate. Over the course of the days/weeks/months, the user can analyze samples to determine if the system is accurately analyzing the concentration levels. If it is determined that the system is not accurate to a desired degree, the user can input an offset value into the system to reflect that error in the measured concentration values so that the concentration measured is corrected.

Results show that real-time chemical concentration monitoring and control are beneficial for advanced solar cell manufacturing. The present invention is capable of accurately predicting the concentration of chemicals and therefore produces desired process results (i.e., a desired texturization pattern) with consistency. The invention reduces the cost of ownership and the overall cost of manufacturing by extending the bath lives. The invention extends the up-time and overall utilization of the system and thereby reduces the cost of manufacturing. The technology of the present invention will also reduce the time for field installation by eliminating the time and resources required to dial-in the correct chemical concentration over many hours and days. With a closed-loop control, the process will no longer require many iterations and tedious work until the desired results are achieved. Thus, the present invention will significantly reduce rework and wafer misprocessing and achieve consistent results.

While the invention has been described with respect to specific examples including presently preferred modes of carrying out the invention, those skilled in the art will appreciate that there are numerous variations and permutations of the above described systems and techniques. It is to be understood that other embodiments may be utilized and structural and functional modifications may be made without departing from the scope of the present invention. Thus, the spirit and scope of the invention should be construed broadly.

What is claimed is:

1. A method of texturizing surfaces of silicon wafers to form solar cells, the method comprising:
providing a closed-loop circulation system comprising a process chamber and a recirculation line fluidly coupled to the process chamber, the recirculation line comprising at least one sensor;
supplying an alkaline solution comprising potassium hydroxide (KOH), isopropyl alcohol (IPA) and deionized water (DIW) to the closed-loop circulation system to form a mixture having a predetermined concentration ratio and a predetermined volume, the mixture filling the process chamber and overflowing into the recirculation line;
submerging a first batch of silicon wafers in the mixture within the process chamber to texturize at least one surface of the silicon wafers of the first batch to form solar cells;
circulating the mixture through the closed-loop circulation system so that the mixture passes through the sensor;
measuring concentration ratio of the mixture and concentration level of an etch by-product within the mixture with the sensor;
comparing the measured concentration ratio to the predetermined concentration ratio to determine whether the measured concentration ratio is within a predetermined range of the predetermined concentration ratio and comparing the concentration level of the etch by-product to a predetermined threshold;
upon determining that the measured concentration ratio is not within the predetermined range of the predetermined concentration ratio, feeding a volume of the KOH, the IPA and/or the DIW into the closed-loop circulation system while bleeding a substantially equal volume of the mixture from the closed-loop circulation system to return the concentration ratio of the mixture back within the predetermined range; and
upon determining that the concentration level of the etch by-product is above the predetermined threshold, feeding a volume of the KOH, IPA and/or DIW into the closed-loop circulation system while bleeding a substantially equal volume of the mixture from the closed-loop circulation system to decrease the concentration level of the etch by-product in the mixture to below the predetermined threshold.

2. The method of claim 1 wherein upon determining that the concentration level of the etch by-product in the mixture is above the predetermined threshold, the volume of the mixture that is bled from the closed-loop circulation system is between approximately 3-8%.

3. The method of claim 1 wherein a concentration of the KOH is between approximately 2-10% by weight of the mixture and a concentration of the IPA is between approximately 2-10% by weight of the mixture.

4. The method of claim 1 wherein texturizing at least one surface of the silicon wafers comprises anisotropically etching the silicon wafers with the alkaline solution to form a pattern of pyramids on the surface of the silicon wafers.

5. The method of claim 1 wherein maintaining the concentration ratio of the mixture within the predetermined range and maintaining the etch by-product level below the predetermined threshold maintains an etch rate of the silicon wafers of the first batch at a consistent rate and maintains a reflectance of the silicon wafers of the first batch at a consistent level.

6. The method of claim 5 wherein the etch rate of the silicon wafers of the first batch is maintained between 0.3 μm/min and 0.5 μm/min throughout a bath life of the mixture.

7. The method of claim 5 wherein the reflectance of the silicon wafers of the first batch is maintained between 8.0% and 10.0% at 950 nm wavelength throughout a bath life of the mixture.

8. The method of claim 5 further comprising:
removing the first batch of silicon wafers from the process chamber, the surface of the silicon wafers of the first batch having a first texturization pattern;
submerging a second batch of silicon wafers in the mixture within the process chamber to texturize at least one surface of the silicon wafers of the second batch, the surface of the silicon wafers of the second batch having a second texturization pattern; and
wherein the first texturization pattern is consistent with the second texturization pattern.

9. The method of claim 8 wherein the etch rate is maintained at a consistent rate and the reflectance is maintained at a uniform level between the silicon wafers of the first batch and the silicon wafers of the second batch.

10. The method of claim 1 wherein a plurality of the solar cells are connected together to form a solar panel.

11. The method of claim 1 wherein the mixture is circulated through the closed-loop circulation system during the feeding of KOH, IPA and/or DIW into the closed-loop circulation system and during the bleeding of the mixture from the closed-loop circulation system.

12. The method of claim 1 wherein the feeding and bleeding occur while the silicon wafers are submerged in the mixture within the process chamber for processing.

13. A method of consistently texturizing surfaces of silicon wafers to form solar cells that are used to create a solar panel, the method comprising:
providing a closed-loop circulation system comprising a process chamber and a recirculation line fluidly coupled to the process chamber, the recirculation line comprising at least one sensor;
supplying an etchant solution comprising an etchant and deionized water (DIW) to the closed-loop circulation system so as to form a mixture having a predetermined concentration ratio and a predetermined volume, the mixture filling the process chamber and overflowing into the recirculation line;
submerging a first batch of silicon wafers in the mixture within the process chamber to texturize at least one surface of the silicon wafers;
circulating the mixture through the closed-loop circulation system so that the mixture passes through the sensor;
measuring concentration ratio of the mixture with the sensor;
comparing the measured concentration ratio to the predetermined concentration ratio to determine whether the measured concentration ratio is within a predetermined range of the predetermined concentration ratio;
upon determining that the measured concentration ratio is not within the predetermined range of the predetermined concentration ratio, feeding a volume of the etchant and/or the DIW into the closed-loop circulation system while bleeding a substantially equal volume of the mixture from the closed-loop circulation system to return the concentration ratio of the mixture back within the predetermined range; and
wherein the feeding and bleeding maintains a first etch rate of the silicon wafers of the first batch at a consistent rate and maintains a first reflectance of the silicon wafers of the first batch at a consistent level.

14. The method of claim 13 wherein a texturization pattern of the silicon wafers of the first batch are uniform.

15. The method of claim 13 further comprising:
removing the first batch of silicon wafers from the process chamber, the silicon wafers of the first batch having a first texturization pattern;
submerging a second batch of silicon wafers in the mixture within the process chamber to texturize the surfaces of the silicon wafers of the second batch, the silicon wafers of the second batch having a second texturization pattern; and
wherein the first texturization pattern is consistent with the second texturization pattern.

16. The method of claim 15 wherein the silicon wafers of the first batch have the first reflectance and the silicon wafers of the second batch have a second reflectance, wherein the first reflectance and the second reflectance are consistent and below 10% at 950 nm wavelength and wherein the first etch rate of the silicon wafers of the first batch and a second etch rate of the silicon wafers of the second batch are maintained at a consistent rate that is below 1.0 μm/min.

17. The method of claim 16 wherein the first reflectance and the second reflectance are between 8% and 10% at 950 nm wavelength and wherein the first etch rate and the second etch rate are between 0.3 μm/min and 0.5 μm/min.

18. The method of claim 13 wherein the etchant is selected from the group consisting of KOH, KOH/IPA, HF/HNO₃, HF/HCL, alkaline NaOH and TMAH.

19. The method of claim 13 further comprising:
measuring concentration level of an etch by-product within the mixture with the sensor,
comparing the concentration level of the etch by-product to a predetermined threshold; and
upon determining that the concentration level of the etch by-product is above the predetermined threshold, feeding a volume of the etchant and/or the DIW into the closed-loop circulation system while bleeding a substantially equal volume of the mixture from the closed-loop circulation system to decrease etch by-product concentration in the mixture.

20. The method of claim 13 wherein the etchant solution comprises KOH at a concentration of 2-10% by weight, IPA at a concentration of 2-10% by weight and the DIW.

21. The method of claim 13 wherein texturizing at least one surface of the silicon wafers comprises anisotropically etching the silicon wafers with the etchant solution to form a pattern of pyramids on the surface of the silicon wafers.

22. A method of consistently texturizing surfaces of silicon wafers to form solar cells, the method comprising:
providing a closed-loop circulation system comprising a process chamber and a recirculation line fluidly coupled to the process chamber, the recirculation line comprising at least one sensor;
supplying an etchant solution comprising deionized water (DIW) and an etchant selected from the group consisting of KOH, KOH/IPA, HF/HNO₃, HF/HCL, alkaline NaOH and TMAH to the closed-loop circulation system so as to form a mixture having a predetermined concentration ratio and a predetermined volume, the mixture filling the process chamber and overflowing into the recirculation line;
submerging a first batch of silicon wafers in the mixture within the process chamber to texturize at least one surface of the silicon wafers by anisotropically etching the silicon wafers of the first batch at a first etch rate to form a first texturization pattern comprising a plurality of pyramids on the surfaces of the silicon wafers of the first batch;
circulating the mixture through the closed-loop circulation system so that the mixture passes through the sensor;
measuring concentration ratio of the mixture with the sensor;
continuously comparing the measured concentration ratio to the predetermined concentration ratio to determine whether the measured concentration ratio is within a predetermined range of the predetermined concentration ratio;
upon determining that the measured concentration ratio is not within the predetermined range of the predetermined concentration ratio, feeding a volume of the etchant and/or the DIW into the closed-loop circulation system while bleeding a substantially equal volume of the mixture from the closed-loop circulation system to return the concentration ratio of the mixture back within the predetermined range;
removing the first batch of silicon wafers from the process chamber;
submerging a second batch of silicon wafers in the mixture within the process chamber to texturize the surfaces of the silicon wafers of the second batch by anisotropically etching the silicon wafers of the second batch at a second etch rate to form a second texturization pattern comprising a plurality of pyramids on the surfaces of the silicon wafers of the second batch;
removing the second batch of silicon wafers from the process chamber; and
wherein the first texturization pattern is consistent with the second texturization pattern and the first etch rate is substantially the same as the second etch rate.
